(19) United States
(12) Patent Application Publication
(10) Pub. No.: US 2026/0026105 A1
(43) Pub. Date: Jan. 22, 2026

(54) DISPLAY PANEL AND DISPLAY DEVICE

(71) Applicant: Guangzhou China Star Optoelectronics Semiconductor Display Technology Co., Ltd., Guangzhou (CN)

(72) Inventors: Mingjong JOU, Guangzhou (CN); Junjie LI, Guangzhou (CN); Lei LIU, Guangzhou (CN); Jun WANG, Guangzhou (CN); Feng LIU, Guangzhou (CN)

(21) Appl. No.: 18/814,670

(22) Filed: Aug. 26, 2024

(30) Foreign Application Priority Data
Jul. 22, 2024 (CN) 202410986224.8

(51) Int. Cl. H01L 27/12; G02F 1/1335; G02F 1/1339; G02F 1/1362

(52) U.S. Cl. CPC H10D 86/60; G02F 1/133514; G02F 1/133528; G02F 1/1339; G02F 1/136204; H10D 86/441

(57) ABSTRACT

A display panel and a display device are provided. The display panel includes an array substrate, a color film substrate, and a first electrical connector, a second electrical connector, and a third electrical connector that are electrically connected with each other. The first electrical connector is provided on a side of the color film substrate which is away from the array substrate, and the second electrical connector is provided on a first side surface of a side of the color film substrate which is adjacent to an electrostatic discharge portion of the array substrate.

### CROSS-REFERENCE TO RELATED APPLICATION

This application claims priority to Chinese Patent Application No. 202410986224.8, filed on Jul. 22, 2024, the disclosure of which is incorporated herein by reference in its entirety.

### TECHNICAL FIELD

The present application relates to the field of displaying technologies, and more particularly, to a display panel and a display device.

### BACKGROUND

The color film substrate of the liquid crystal display device generally has a problem of electrostatic accumulation. When the electrostatic accumulation occurs to a certain extent, the electrostatic field generated by the static charges will interfere with the electric field of the liquid crystal molecules inside the display panel.

In the related art, a transparent conductive layer is generally provided on a side of the color film substrate facing away from the array substrate, and silver adhesive is coated at a bridging point between the transparent conductive layer on the back side of the color film substrate and the ground terminal of the array substrate so as to lead out static charges. However, because the silver adhesive is easily oxidized, corroded, or even detached, the contact between the transparent conductive layer and the ground terminal is poor, and static electricity on the back side of the color film substrate cannot be eliminated, thereby causing the abnormal displaying of the display panel.

### SUMMARY

The present application provides a display panel and a display device, so as to improve the technical problem that the abnormal displaying occurs in a conventional liquid crystal display device because the static charges in the color film substrate cannot be lead out in time.

To solve the above problem, the technical solution provided in the present application is as follows.

In one or more embodiments, it is provided a display panel including a first region and a second region at a side of the first region, in which the display panel includes: an array substrate including a first substrate and an electrostatic discharge portion provided on the first substrate, in which the electrostatic discharge portion is provided in the second region; a color film substrate disposed to be opposite to the array substrate, in which the color film substrate includes an edge inwardly retracted relative to an edge of the array substrate, and the color film substrate is located in the first region; a first electrical connector disposed on a side of the color film substrate which is away from the array substrate; a second electrical connector disposed on a first side surface of a side of the color film substrate which is adjacent to the electrostatic discharge portion, in which the second electrical connector is electrically connected to the first electrical connector; and a third electrical connector located in the second region, in which the third electrical connector is disposed on a side of the array substrate which is adjacent to the color film substrate and disposed to be adjacent to the first side surface, and the third electrical connector is electrically connected to the second electrical connector and the electrostatic discharge portion.

In one or more embodiments, a maximum distance between a surface of a side of the third electrical connector which is away from the array substrate and the first substrate is less than a maximum distance between a surface of a side of the color film substrate which is away from the array substrate and the first substrate.

In one or more embodiments, an orthographic projection of the third electrical connector on the first substrate at least partially overlaps an orthographic projection of the electrostatic discharge portion on the first substrate.

In one or more embodiments, the display panel further includes a bonding portion provided in the second region, in which the bonding portion is provided on a side of the electrostatic discharge portion which is away from the first side surface, and the bonding portion is insulated from the electrostatic discharge portion and the third electrical connector.

In one or more embodiments, the display panel further includes a sealant disposed between the array substrate and the color film substrate, in which the sealant is disposed adjacent to the first side surface; in which the second electrical connector extends from an end of the first side surface which is away from the array substrate toward an end of the first side surface which is adjacent to the array substrate, and the second electrical connector at most partially overlaps with the sealant.

In one or more embodiments, the display panel further includes a first polarizer disposed on a side of the first electrical connector which is away from the color film substrate; and a second polarizer disposed on a side of the first substrate which is away from the color film substrate, in which the second polarizer includes an edge retracted inwardly relative to an edge of the first polarizer; in which the color film substrate further includes a first light-blocking member disposed adjacent to the first side surface, and the second polarizer at least partially overlaps the first light-blocking member.

In one or more embodiments, the first polarizer further includes an extension section extending in a direction away from the first side surface, and the extension section includes an edge retracted inwardly with respect to the edge of the array substrate; in which the electrostatic discharge portion is located in an orthographic projection of the extension section on the array substrate.

In one or more embodiments, the first polarizer further includes an extension section extending in a direction away from the first side surface; the array substrate includes a second side surface adjacent to the bonding portion, and an orthographic projection of the second side surface on the first polarizer is located within the extension section.

In one or more embodiments, the display panel further includes a second light-blocking member located in the second region, in which the second light-blocking member is filled between the extension section and the array substrate.

In one or more embodiments, a material of the third electrical connector includes conductive silver adhesive.

According to one or more embodiments, it is provided a display device including the above-mentioned display panel and an outer frame; in which the outer frame includes a bottom plate and a side plate provided on a side of the bottom plate, in which the side plate and the bottom plate enclose to form a receiving chamber, and at least a part of the display panel is provided in the receiving chamber; in which an orthographic projection of the side plate on the bottom plate is non-overlapped with an orthographic projection of the display panel on the bottom plate.

### BRIEF DESCRIPTION OF THE DRAWINGS

The technical solution and other beneficial effects of the present application will be apparent from the following detailed description of specific embodiments thereof, taken in conjunction with the accompanying drawings.

FIG. 1 is a structural diagram of a display panel according to one or more embodiments of the present application;

FIG. 2 is another structural diagram of a display panel according to one or more embodiments of the present application;

FIG. 3 is yet another structural diagram of a display panel according to one or more embodiments of the present application;

FIG. 4 is a top view of a sealant and a second electrical connector in a display panel according to one or more embodiments of the present application;

FIG. 5 is a top view of a display panel according to one or more embodiments of the present application;

FIG. 6 is yet another structure diagram of a display panel according to one or more embodiments of the present application;

FIG. 7 is yet another structure diagram of a display panel according to one or more embodiments of the present application; and

FIG. 8 is a structural diagram of a display device according to one or more embodiments of the present application.

### DETAILED DESCRIPTION

The technical solution in the embodiments of the present application will be clearly and completely described with reference to the accompanying drawings. It will be apparent that the described embodiments are only a part of the embodiments of the present application, and not all embodiments of the present application. Based on the embodiments in the present application, all other embodiments obtained by a person skilled in the art without involving any inventive effort are within the scope of the present application.

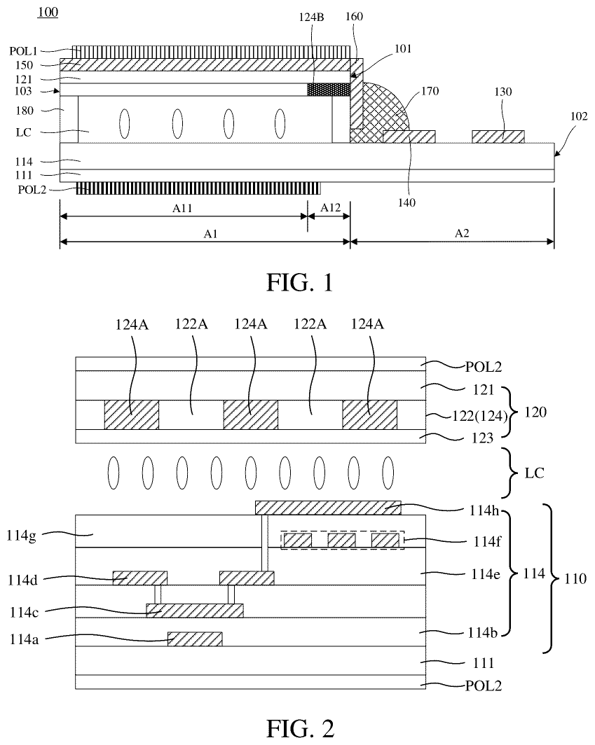

Referring to FIGS. 1 to 7, according to one or more embodiments of the present application, it is provided a display panel 100 including a first region A1 and a second region A2 located at a side of the first region A1. The display panel 100 includes an array substrate 110, a color film substrate 120 disposed to be opposite to the array substrate 110, and a liquid crystal layer LC located between the array substrate 110 and the color film substrate 120.

In the present embodiments, since the bonding portion 130 needs to be provided on the array substrate 110, the color film substrate 120 includes an edge inwardly retracted with respect to an edge of the array substrate 110. For example, the color film substrate 120 has a first side surface 101 adjacent to an electrostatic discharge portion 140, the array substrate 110 includes a second side surface 102 adjacent to the bonding portion 130, and the first side surface 101 is inwardly retracted with respect to the second side surface 102.

In the present embodiments, the first region A1 may be a region in which the color film substrate 120 is located, and the second region A2 may be a region of the array substrate 110 which does not overlap the color film substrate 120.

In the present embodiments, the array substrate 110 includes a first substrate 111 and the electrostatic discharge portion 140 provided on the first substrate 111. The electrostatic discharge portion 140 is provided in the second region A2, and the electrostatic discharge portion 140 is configured to discharge static charges, thereby avoiding a problem of electrostatic concentration in the display panel 100.

In the present embodiments, the display panel 100 further includes a first electrical connector 150, a second electrical connector 160, and a third electrical connector 170. The first electrical connector 150 is provided on a side of the color film substrate 120 which is away from the array substrate 110. The second electrical connector 160 is provided on the first side surface 101 of a side of the color film substrate 120 which is adjacent to the electrostatic discharge portion 140. The second electrical connector 160 is electrically connected to the first electrical connector 150. The third electrical connector 170 is located in the second region A2. The third electrical connector 170 is provided on a side of the array substrate 110 which is adjacent to the color film substrate 120 and is arranged near the first side surface 101. The third electrical connector 170 is electrically connected to the second electrical connector 160 and the electrostatic discharge portion 140.

In the present application, the second electrical connector 160 electrically connected to the first electrical connector 150 is provided at the side of the color film substrate 120, and the third electrical connector 170 is electrically connected to the second electrical connector 160 and the electrostatic discharge portion 140. In this way, the static charges in the first electrical connector 150 are transferred to the electrostatic discharge portion 140 through the second electrical connector 160 and the third electrical connector 170 for discharge, so that the static charges in the first electrical connector 150 can be timely introduced into the electrostatic discharge portion 140, thereby improving the displaying effect of the display panel 100.

It should be noted that a maximum distance between a surface of a side of the third electrical connector 170 which is away from the array substrate 110 and the first substrate 111 is less than a maximum distance between a surface of a side of the color film substrate 120 which is away from the array substrate 110 and the first substrate 111. That is, the surface of the side of the third electrical connector 170 which is away from the array substrate 110 is lower than the surface of the side of the color film substrate 120 which is away from the array substrate 110.

For example, in the structure shown in FIG. 2, the color film substrate 120 may include a second substrate 121 and a color resist layer 122 on the second substrate 121. The surface of the side of the third electrical connector 170 which is away from the array substrate 110 is lower than the surface of the side of the second substrate 121 which is away from the array substrate 110.

It should be noted that the first electrical connector 150 may be laid on wholly or may be existed in the form of a pattern, which is mainly used for collecting the static charges in the product. When the static charges are collected to a certain amount, the electrostatic field generated by the static charges in the first electrical connector 150 will interfere with the electric field of the liquid crystal molecules inside the display panel. The second electrical connector 160 and the third electrical connector 170 of the present application may be arranged to transfer the charges in the first electrical connector 150 to the electrostatic discharge portion 140, so as to avoid the problem of electrostatic concentration in the first electrical connector 150.

It should be noted that since light rays introduced into the display panel 100 by the backlight module (not shown) need to be led out from the color film substrate 120. So, the material of the first electric connector 150 of the present application needs to be provided as a transparent conductive material, such as indium tin oxide.

It should be noted that the material of the third electrical connector 170 of the present application may include a conductive adhesive, such as conductive silver adhesive.

It should be noted that the electrostatic discharge portion 140 of the present application may include multiple grounded terminals or may be of a monolithic terminal structure.

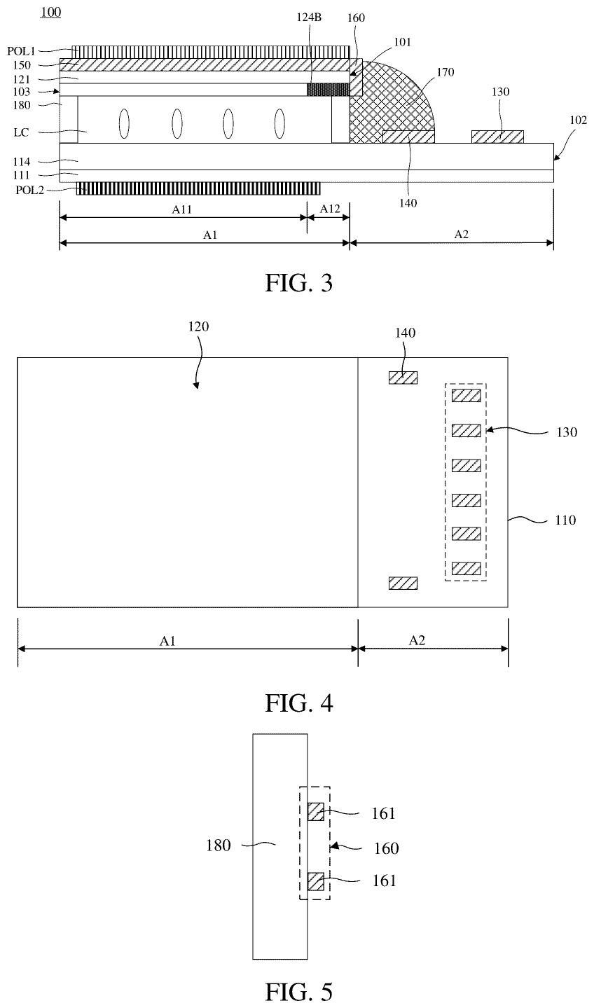

Referring to FIGS. 1 and 3, the display panel 100 further includes a bonding portion 130 in the second region A2. The bonding portion 130 is provided at a side of the electrostatic discharge portion 140 which is away from the first side surface 101. The bonding portion 130 is used for bonding connection with the transmission member 210. For example, the transmission member 210 may be a flip-chip thin film.

Referring to FIGS. 1 and 3, the array substrate 110 further includes a bonding portion 130 provided in the second region A2. The bonding portion 130 is provided on a side of the electrostatic discharge portion 140 which is away from the color film substrate 120. In one or more embodiments, if the conductive silver adhesive is directly electrically connected to the first electrical connector 150, an end of the conductive silver adhesive needs to be lap-jointed on the surface of the first electrical connector 150, and the other end of the conductive silver adhesive needs to be electrically connected to the electrostatic discharge terminal. The conductive silver adhesive is located to be close to the bonding portion 130. In this way, in order to avoid that the terminal in the bonding portion 130 is electrically connected to the conductive silver adhesive, the bonding portion 130 needs to have a certain safe distance from the conductive silver adhesive. When the conductive silver adhesive is coated, the width of the conductive silver adhesive also increases correspondingly along with the height thereof increasing, so that the third electrical connector 170 completely covers the electrostatic discharge portion 140 and extends toward the region where the bonding portion 130 is located. Therefore, in order to avoid the influence of the electrostatic discharge portion 140 on the bonding portion 130, the bonding portion 130 needs to set outwardly, so that the arrangement of the conductive silver adhesive increases the occupied space in the side frame.

In the present embodiment, the second electrical connector 160 is provided on the first side surface 101 of the color film substrate 120 so that the third electrical connector 170 does not need to be lap-jointed on the surface of the first electrical connector 150, thereby avoiding a problem that the first electrical connector is in poor contact with the electrostatic discharge portion 140 due to oxidation, corrosion or even detached of the third electrical connector. Meanwhile, the surface of the side of the third electrical connector 170 which is away from the array substrate 110 is lower than the surface of the side of the color film substrate 120 which is away from the array substrate 110, so that the height of the third electrical connector 170 is reduced, and the space in the side frame which is occupied by the third electrical connector 170 may be also reduced, thereby realizing the design of the narrow frame of the display panel 100.

The technical solution of the present application will now be described in connection with specific examples.

Referring to FIG. 2, an array substrate 110 may include a first substrate 111 and an array layer 114 disposed on the first substrate 111. The materials of both the first substrate 111 and the second substrate 121 may be made of materials such as glass, quartz, or polyimide.

In the present embodiments, the array layer 114 may include multiple thin film transistors. The type of the thin film transistor may be an etching barrier type, a back-channel etching type; or the thin film transistor may be a thin film transistor, such as a bottom-gate thin film transistor, a top-gate thin film transistor, according to the positions of the gate and the active layer 114c. For example, the bottom-gate thin film transistor may include a gate layer 114a on the first substrate 111, a gate insulating layer 114b on the gate layer 114a, an active layer 114c on the gate insulating layer 114b, a source/drain layer 114d on the active layer 114c, and a passivation layer 114e on the source/drain layer 114d, a common electrode layer 114f on the passivation layer 114e, a planarization layer 114g on the common electrode layer 114f, and a pixel electrode layer 114h on the planarization layer 114g. An electric field formed by the common electrode layer 114f and the pixel electrode layer 114h may drive the deflection of the liquid crystal molecules in the liquid crystal layer LC.

In the display panel 100 of the present application, the first region A1 includes a first sub-region A11 and a second sub-region A12. The first sub-region A11 is a display region of the display panel 100. The second sub-region A12 is provided around the first sub-region A11. The second sub-region A12 and the second region A2 are non-display regions of the display panel 100. Referring to FIGS. 1 and 2, the display panel 100 further includes a sealant 180 disposed between the array substrate 110 and the color film substrate 120. The sealant 180 is disposed within the second sub-region A12.

Referring to FIG. 2, the color film substrate 120 further includes a light-blocking layer 124 disposed in the same layer as the color resist layer 122. The color resist layer 122 includes a plurality of color resist units 122A disposed at intervals. The light-blocking layer 124 includes a light-blocking unit 124A disposed between two adjacent color resist units 122A. The light-blocking units 124A are disposed in the first sub-region A11. The plurality of light-blocking units 124A may be in a network structure.

In the present embodiment, since the second sub-region A12 is a non-display region, the light-blocking layer 124 may further include a first light-blocking member 124B provided in the second sub-region A12. The plurality of light-blocking units 124A may be continuous with the first light-blocking member 124B. The material of the light-blocking layer 124 may be a black organic material.

In the present embodiment, each of the electrostatic discharge portion 140 and the bonding portion 130 of the present application may be formed by at least one layer of metal in the array layer 114. For example, each of the electrostatic discharge portion 140 and the bonding portion 130 may be of a laminated conductive structure including the pixel electrode layer 114h and the source/drain layer 114d.

In the display panel 100 of the present application, referring to FIGS. 1 and 3, an orthographic projection of the third electrical connector 170 on the first substrate 111 at least partially overlaps with an orthographic projection of the electrostatic discharge 140 on the first substrate 111.

Since the third electrical connector 170 needs to be electrically connected to the electrostatic discharge 140, the third electrical connector 170 needs to be at least partially overlapped with the electrostatic discharge 140, for example, the structure shown FIG. 1. In order to ensure the electrical connection of the third electrical connector 170 to the electrostatic discharge portion 140, the third electrical connector 170 may cover the electrostatic discharge portion 140 completely, for example, the structure shown in FIG. 3. Meanwhile, since the design of the narrow frame of the product needs to be considered, the boundary at the side of the third electrical connector 170 which is away from the color film substrate 120 may be located on the same plane as the boundary at the side of the electrostatic discharge portion 140 which is away from the color film substrate 120 in the present application.

Referring to FIGS. 1 and 3, since the electrostatic discharge portion 140 may be a terminal that is grounded, the bonding portion 130 is insulated from the electrostatic discharge portion 140 and the third electrical connector 170 to avoid shorting the bonding portion 130 to the electrostatic discharge portion 140 and the third electrical connector 170. Meanwhile, referring to FIG. 4, when the electrostatic discharge portion 140 includes two grounded terminals, the two grounded terminals are provided at two ends of the second region A2. And, the bonding terminals in the bonding portion 130 and the grounded terminals may be provided in a misalignment manner in the present application, thereby further preventing the bonding portion 130 from shorting to the electrostatic discharge portion 140 and the third electrical connector 170.

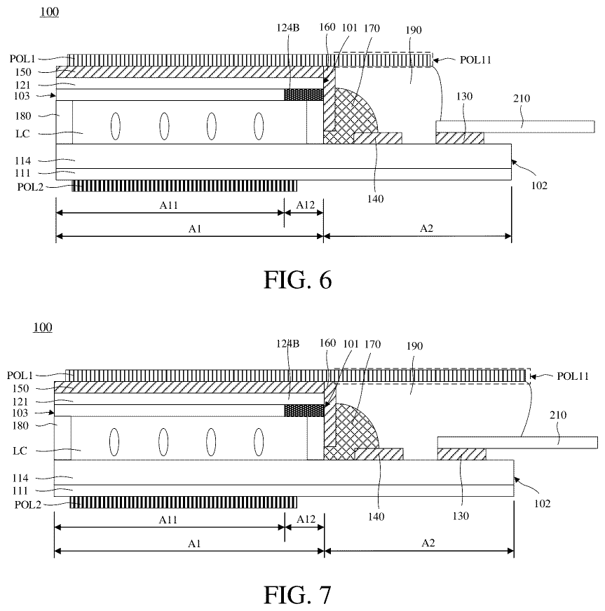

In the present embodiment, referring to FIGS. 6 to 8, since the distance between the electrostatic discharge portion 140 and the end face of the transmission member 210 which is adjacent to the color film substrate 120 is smaller than the distance between the bonding portion 130 and the electrostatic discharge portion 140, the third electrical connector 170 may be lap-jointed with the transmission member 210 at the time of coating. And, the corresponding metal lines are disposed in the transmission member 210, and thus the third electrical connector 170 needs to be provided separately from the transmission member 210 in the present application.

In the present embodiment, the second electrical connector 160 may be disposed on the first side surface 101 by a physical deposition process, and the second electrical connector 160 may be disposed on the whole first side surface 101. Alternatively, referring to FIG. 5, the second electrical connector 160 includes a plurality of sub-connectors 161 spaced apart, and each of the sub-connectors 161 is electrically connected to the first electrical connector 150.

In the present embodiment, the second electrical connector 160 extends from an end of the first side surface 101 which is away from the array substrate 110 toward an end of the first side surface 101 which is adjacent to the array substrate 110. And, the second electrical connector 160 at most partially overlaps with the sealant 180.

Referring to FIG. 1, the second electrical connector 160 covers the first side surface 101 of the color film substrate 120, while the second electrical connector 160 extends toward the end of the array substrate 110 and at least partially overlaps with the end surface of the side of the sealant 180 which is adjacent to the bonding portion 130.

In the present embodiment, since the material of the third electrical connector 170 is conductive silver adhesive, if the extension length of the second electrical connector 160 on the first side surface 101 is longer, the required height of the conductive silver adhesive will be decreased, and the width of the conductive silver adhesive will be decreased. Therefore, the present application allows the second electrical connector 160 to extend to the end surface of the side of the sealant 180 which is adjacent to the bonding portion 130, thereby reducing the height of the third electrical connector 170, and further reducing the width of the third electrical connector 170. So, it may avoid the width in the second region A2 which is occupied by the third electrical connector 170, and thus the narrow frame design of the product may be realized.

In the present embodiments, the material of the second electrical connector 160 may be indium tin oxide.

Referring to FIG. 3, the second electrical connector 160 of the present application may also be non-overlapped with the sealant 180. That is, the second electrical connector 160 is provided only on the first side surface 101 of the color film substrate 120.

Referring to FIGS. 1 and 3, the display panel 100 further includes first and second polarizers POL1 and POL2 disposed on two sides of the display panel 100. The first polarizer POL1 is disposed on a side of the color film substrate 120 which is away from the array substrate 110, and the second polarizer POL2 is disposed on a side of the array substrate 110 which is away from the color film substrate 120. That is, the first polarizer POL1 is disposed on the side of the first electrical connector 150 which is away from the color film substrate 120, and the second polarizer POL2 is disposed on the side of the first substrate 111 which is away from the color film substrate 120.

In the present embodiments, the second polarizer POL2 is disposed close to the backlight module, and a part of the structure in the backlight module is in contact with the display panel 100. So, in order to avoid interference between the second polarizer POL2 and the backlight module, the edge of the second polarizer POL2 in the present application is inwardly retracted relative to the edge of the first polarizer POL1, that is, the area of the second polarizer POL2 is reduced.

For example, referring to FIGS. 1 and 3, the color film substrate 120 further includes a third side surface 103 opposite to the first side surface 101. The second polarizer POL2 has an end surface close to the third side surface 103. The end surface of the second polarizer POL2 is retracted inwardly with respect to the end surface of the first polarizer POL1 which is close to the third side surface 103 by a distance of 0.05 mm to 0.2 mm.

In the present embodiments, referring to FIG. 1 and FIG. 3, since the second sub-region A12 is the non-display region, the second polarizer POL2 is at least partially overlapped with the first light-blocking member 124B in order to prevent light rays, which is introduced into the display panel 100 from the backlight module, from leaking out from the edge of the display panel 100.

In the display panel 100 of the present application, referring to FIG. 6, the first polarizer POL1 further includes an extension section POL11 extending in a direction away from the first side surface 101. The extension section POL11 includes an edge inwardly retracted with respect to an edge of the array substrate 110, and the electrostatic discharge section 140 is located in the orthographic projection of the extension section POL11 on the array substrate 110. Meanwhile, the display panel 100 further includes a second light-blocking member 190 located in the second region A2. The second light-blocking member 190 is filled between the extension section POL11 and the array substrate 110.

In this embodiment, the material of the second light-blocking member 190 may be a black light-blocking material.

In the present embodiments, the first polarizer POLI extends to an outside of the color film substrate 120 while the region between the extension section POL11 and the array substrate 110 is filled by using the black light-blocking material.

Alternatively, referring to FIG. 7, the array substrate 110 includes a second side surface 102 which is adjacent to the bonding portion 130. The orthographic projection of the second side surface 102 on the first polarizer POLI is positioned within the extension section POL11. On the basis of FIG. 6, the length of the extension section POL11 in FIG. 7 is further increased and exceeds beyond the boundary of the array substrate 110. The region between the extension section POL11 and the array substrate 110 is filled with the black light-blocking material, and the edge of the display panel is shielded by the black light-blocking material. So, the outer frame of the module of the product does not need to be extended to directly above the bonding portion 130, which reduces the width of the outer frame of the module, and realizes the non-frame design of the four sides of the product.

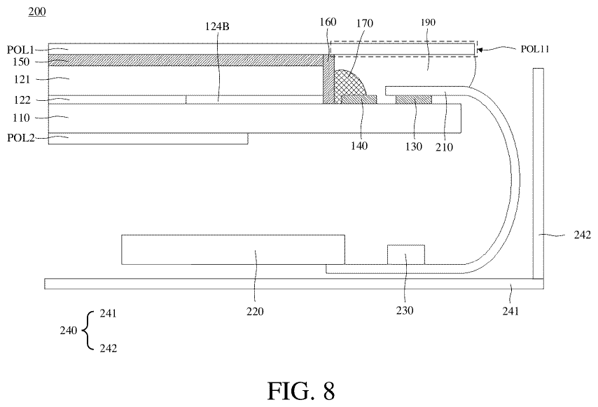

Referring to FIG. 8, according to embodiments of the present application, it is provided a display device 200 including the above-mentioned display panel 100, and a transmission member 210 bonded to a bonding portion 130 of the display panel 100, a printed circuit board 220, and a driver chip 230. The transmission member 210 is bent to the side of the display panel 100 which faces away from the color film substrate 120. The transmission member 210 may be electrically connected to the bonding terminal in the bonding portion 130 by an anisotropic conductive adhesive.

In the present embodiment, the display device 200 may further include a touch control layer (not shown) integrated in the display panel 100. For example, the touch control layer may be disposed between the second polarizer POL2 and the first substrate 111, or the touch control layer may be disposed between the first polarizer POL1 and the second substrate 121.

Referring to FIG. 8, the display device 200 further includes an outer frame 240 including a bottom plate 241, and a side plate 242 provided at a side of the bottom plate 241. The side plate 242 and the bottom plate 241 enclose a receiving chamber. At least a portion of the display panel 100 is provided in the receiving chamber. An orthographic projection of the side plate 242 on the bottom plate 241 and an orthographic projection of the display panel 100 on the bottom plate 241 are not overlapped.

On the basis of FIG. 7, referring to FIG. 8, the boundary of the extension section POL11 exceeds beyond the boundary of the array substrate 110, the region between the extension section POL11 and the array substrate 110 is filled with the black light-blocking material, and the edge of the display panel is shielded. In this way, the side plate 242 does not need to extend to directly above the bonding portion 130, thereby realizing the non-frame design on the four sides of the product.

In the above-mentioned embodiments, the description of each embodiment has its own emphasis, and the parts not described in detail in a certain embodiment may be referred to the related description of other embodiments.

The principles and the embodiments of the present application have been elucidated with reference to specific examples, and the description of the above examples is merely intended to assist in understanding the technical solution of the present application and the core idea thereof. It will be appreciated by those of ordinary skill in the art that modifications may still be made to the technical solutions described in the foregoing embodiments, or equivalents may be made to some of the technical features therein. These modifications or substitutions do not depart the essence of the corresponding technical solutions from the scope of the technical solutions of the embodiments of the present application.

What is claimed is:

1. A display panel comprising a first region and a second region at a side of the first region, the display panel comprising:
an array substrate comprising a first substrate and an electrostatic discharge portion provided on the first substrate, wherein the electrostatic discharge portion is provided in the second region;
a color film substrate disposed to be opposite to the array substrate, wherein the color film substrate comprises an edge inwardly retracted relative to an edge of the array substrate, and the color film substrate is located in the first region;
a first electrical connector disposed on a side of the color film substrate which is away from the array substrate;
a second electrical connector disposed on a first side surface of a side of the color film substrate which is adjacent to the electrostatic discharge portion, wherein the second electrical connector is electrically connected to the first electrical connector; and
a third electrical connector located in the second region, wherein the third electrical connector is disposed on a side of the array substrate which is adjacent to the color film substrate and disposed to be adjacent to the first side surface, and the third electrical connector is electrically connected to the second electrical connector and the electrostatic discharge portion.

2. The display panel according to claim 1, wherein a maximum distance between a surface of a side of the third electrical connector which is away from the array substrate and the first substrate is less than a maximum distance between a surface of a side of the color film substrate which is away from the array substrate and the first substrate.

3. The display panel according to claim 1, wherein an orthographic projection of the third electrical connector on the first substrate at least partially overlaps an orthographic projection of the electrostatic discharge portion on the first substrate.

4. The display panel according to claim 3, further comprising a bonding portion provided in the second region, wherein the bonding portion is provided on a side of the electrostatic discharge portion which is away from the first side surface, and the bonding portion is insulated from the electrostatic discharge portion and the third electrical connector.

5. The display panel according to claim 1, further comprising a sealant disposed between the array substrate and the color film substrate, wherein the sealant is disposed adjacent to the first side surface;
wherein the second electrical connector extends from an end of the first side surface which is away from the array substrate toward an end of the first side surface which is adjacent to the array substrate, and the second electrical connector at most partially overlaps with the sealant.

6. The display panel according to claim 1, further comprising:
a first polarizer disposed on a side of the first electrical connector which is away from the color film substrate; and
a second polarizer disposed on a side of the first substrate which is away from the color film substrate, wherein the second polarizer comprises an edge retracted inwardly relative to an edge of the first polarizer;
wherein the color film substrate further comprises a first light-blocking member disposed adjacent to the first side surface, and the second polarizer at least partially overlaps the first light-blocking member.

7. The display panel according to claim 6, wherein the first polarizer further comprises an extension section extending in a direction away from the first side surface, and the extension section comprises an edge retracted inwardly with respect to the edge of the array substrate;
wherein the electrostatic discharge portion is located in an orthographic projection of the extension section on the array substrate.

8. The display panel of claim 6, wherein the first polarizer further comprises an extension section extending in a direction away from the first side surface; the array substrate comprises a second side surface adjacent to the bonding portion, and an orthographic projection of the second side surface on the first polarizer is located within the extension section.

9. The display panel according to claim 7, further comprising a second light-blocking member located in the second region, wherein the second light-blocking member is filled between the extension section and the array substrate.

10. The display panel according to claim 8, further comprising a second light-blocking member located in the second region, wherein the second light-blocking member is filled between the extension section and the array substrate.

11. The display panel according to claim 1, wherein a material of the third electrical connector comprises conductive silver adhesive.

12. A display device, comprising:
a display panel comprising a first region and a second region at a side of the first region, the display panel comprising:
an array substrate comprising a first substrate and an electrostatic discharge portion provided on the first substrate, wherein the electrostatic discharge portion is provided in the second region;
a color film substrate disposed to be opposite to the array substrate, wherein the color film substrate comprises an edge inwardly retracted relative to an edge of the array substrate, and the color film substrate is located in the first region;
a first electrical connector disposed on a side of the color film substrate which is away from the array substrate;
a second electrical connector disposed on a first side surface of a side of the color film substrate which is adjacent to the electrostatic discharge portion, wherein the second electrical connector is electrically connected to the first electrical connector; and
a third electrical connector located in the second region, wherein the third electrical connector is disposed on a side of the array substrate which is adjacent to the color film substrate and disposed to be adjacent to the first side surface, and the third electrical connector is electrically connected to the second electrical connector and the electrostatic discharge portion; and
an outer frame comprising a bottom plate and a side plate provided on a side of the bottom plate, wherein the side plate and the bottom plate enclose to form a receiving chamber, and at least a part of the display panel is provided in the receiving chamber;
wherein an orthographic projection of the side plate on the bottom plate is non-overlapped with an orthographic projection of the display panel on the bottom plate.

13. The display device according to claim 12, wherein a maximum distance between a surface of a side of the third electrical connector which is away from the array substrate and the first substrate is less than a maximum distance between a surface of a side of the color film substrate which is away from the array substrate and the first substrate.

14. The display device according to claim 12, wherein an orthographic projection of the third electrical connector on the first substrate at least partially overlaps an orthographic projection of the electrostatic discharge portion on the first substrate.

15. The display device according to claim 14, wherein the display panel further comprises a bonding portion provided in the second region, wherein the bonding portion is provided on a side of the electrostatic discharge portion which is away from the first side surface, and the bonding portion is insulated from the electrostatic discharge portion and the third electrical connector.

16. The display device according to claim 12, wherein the display panel further comprises a sealant disposed between the array substrate and the color film substrate, wherein the sealant is disposed adjacent to the first side surface;
wherein the second electrical connector extends from an end of the first side surface which is away from the array substrate toward an end of the first side surface which is adjacent to the array substrate, and the second electrical connector at most partially overlaps with the sealant.

17. The display device according to claim 12, wherein the display panel further comprises:
a first polarizer disposed on a side of the first electrical connector which is away from the color film substrate; and
a second polarizer disposed on a side of the first substrate which is away from the color film substrate, wherein the second polarizer comprises an edge retracted inwardly relative to an edge of the first polarizer;
wherein the color film substrate further comprises a first light-blocking member disposed adjacent to the first side surface, and the second polarizer at least partially overlaps the first light-blocking member.

18. The display device according to claim 17, wherein the first polarizer further comprises an extension section extending in a direction away from the first side surface, and the extension section comprises an edge retracted inwardly with respect to the edge of the array substrate;
wherein the electrostatic discharge portion is located in an orthographic projection of the extension section on the array substrate.

19. The display device according to claim 17, wherein the first polarizer further comprises an extension section extending in a direction away from the first side surface; the array substrate comprises a second side surface adjacent to the bonding portion, and an orthographic projection of the second side surface on the first polarizer is located within the extension section.

20. The display device according to claim 18, wherein the display panel further comprises a second light-blocking member located in the second region, wherein the second light-blocking member is filled between the extension section and the array substrate.
